(19) United States
(12) Patent Application Publication
(10) Pub. No.: US 2025/0315565 A1
(43) Pub. Date: Oct. 9, 2025

(54) PROCESS RECIPE TRANSFER AND CHAMBER MATCHING BY MODELING

(71) Applicant: Applied Materials, Inc., Santa Clara, CA (US)

(72) Inventors: Ala Moradian, San Jose, CA (US); Karthik Ramanathan, Karnataka (IN); Lori Washington, San Jose, CA (US); Ying Yin Chang, Santa Clara, CA (US); Jyothi Rajeevan, Cupertino, CA (US)

(21) Appl. No.: 19/172,496

(22) Filed: Apr. 7, 2025

(30) Foreign Application Priority Data
Apr. 9, 2024 (IN) 202441028811

(51) Int. Cl. G06F 30/17; G06F 30/27

(52) U.S. Cl. CPC G06F 30/17; G06F 30/27

(57) ABSTRACT

A method includes obtaining first output from a first model. The first output is associated with a first process chamber. The first output includes one or more target performance metrics for the first process chamber. The method further includes providing the one or more target performance metrics as input to a second model. The second model is associated with a second process chamber. The method further includes obtaining second output from the second model. The second output includes first process parameters in association with the second process chamber. The first process parameters are predicted to correspond with the one or more target performance metrics. The method further includes performing a corrective action in view of the second output.

### RELATED APPLICATIONS

This application claims the benefit of Indian Provisional Patent Application No. 202441028811, filed Apr. 9, 2024, entitled “PROCESS RECIPE TRANSFER AND CHAMBER MATCHING BY MODELING,” which is incorporated by reference herein.

### TECHNICAL FIELD

The present disclosure relates to methods associated with modeling operations for improving processing. Specifically, the present disclosure is related to using modeling operations for process recipe transfer and chamber matching.

### BACKGROUND

Products may be produced by performing one or more manufacturing processes using manufacturing equipment. For example, semiconductor manufacturing equipment may be used to produce substrates via semiconductor manufacturing processes. Products are to be produced with particular properties, suited for a target application. Product properties may include repeatability, e.g., freedom of products from defects. Machine learning models are used in various process control and predictive functions associated with manufacturing equipment. Machine learning models are trained using data associated with the manufacturing equipment. Outputs of machine learning models may be used to adjust or improve manufacturing outputs in manufacturing processes.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular embodiments of the disclosure or any scope of the claims. Its sole purpose is to present some concepts of the disclosure in a simplified form as a prelude to the more detailed description that is presented later.

In one aspect of the present disclosure, a method includes obtaining, from a first model associated with a first process chamber, first output. The first output includes one or more target performance metrics of the first process chamber. The method further includes providing, to a second model associated with a second process chamber, the one or more target performance metrics as input. The method further includes obtaining, from the second model, second output. The second output includes process parameters in association with the second process chamber. The process parameters are predicted to correspond with the one or more target performance metrics. The method further includes performing a corrective action in view of the second output.

In another aspect of the present disclosure, a non-transitory machine-readable storage medium stores instructions which, when executed, cause a processing device to perform operations. The operations include obtaining, from a first model associated with a first process chamber, first output. The first output includes one or more target performance metrics of the first process chamber. The operations further include providing, to a second model associated with a second process chamber, the one or more target performance metrics as input. The operations further include obtaining, from the second model, second output. The second output includes process parameters in association with the second process chamber. The process parameters are predicted to correspond with the one or more target performance metrics. The operations further include performing a corrective action in view of the second output.

In another aspect of the present disclosure, a system includes memory and a processing device coupled to the memory. The processing device is configured to obtain, from a first model associated with a first process chamber, first output. The first output includes one or more target performance metrics of the first process chamber. The processing device is further configured to provide, to a second model associated with a second process chamber, the one or more target performance metrics as input. The processing device is further configured to obtain, from the second model, second output. The second output includes process parameters in association with the second process chamber. The process parameters are predicted to correspond with the one or more target performance metrics. The processing device is further configured to perform a corrective action in view of the second output.

### BRIEF DESCRIPTION OF THE DRAWINGS

The present disclosure is illustrated by way of example, and not by way of limitation in the figures of the accompanying drawings.

FIG. 1 is a block diagram illustrating an exemplary system architecture, according to some embodiments.

FIG. 2 depicts a block diagram of a system including an example data set generator for creating data sets for one or more supervised models, according to some embodiments.

FIG. 3 is a block diagram illustrating a system for generating output data, according to some embodiments.

FIG. 4A is a flow diagram of a method for generating a data set for a machine learning model, according to some embodiments.

FIG. 4B is a flow diagram of a method for utilizing models for adjusting performance of a process chamber, according to some embodiments.

FIG. 4C is a flow diagram of a method for training a machine learning model for performing chamber matching operations, according to some embodiments.

FIG. 5 is a block diagram depicting a flow for converting a process recipe for use in a second process system, according to some embodiments.

FIG. 6 is a block diagram illustrating a computer system, according to some embodiments.

### DETAILED DESCRIPTION

Described herein are technologies related to a platform for transferring process recipes between chambers. Manufacturing equipment is used to produce products, such as substrates (e.g., wafers, semiconductors). Manufacturing equipment may include a manufacturing or processing chamber to separate the substrate from the environment. The properties of produced substrates are to meet target values to facilitate specific functionalities. Manufacturing parameters are selected to produce substrates that meet the target property values. Many manufacturing parameters (e.g., hardware parameters, process parameters, etc.) contribute to the properties of processed substrates. Manufacturing systems may control parameters by specifying a set point for a property value and receiving data from sensors disposed within the manufacturing chamber, and making adjustments to the manufacturing equipment until the sensor readings match the set point. Consistent performance between a fleet of process chambers, which may include chambers of various ages, constituent components, designs, models, or the like, may increase efficiency of a manufacturing facility. Physics-based models, statistical models, and trained machine learning models may be utilized to improve performance of manufacturing equipment.

Considerable effort may be dedicated to generating and/or optimizing a process recipe for a target substrate manufacturing procedure. For example, process recipes may be generated to manufacture substrates meeting target performance metrics. Process recipes may further be refined to achieve additional goals (such as increasing throughput, decreasing manufacturing costs, decreasing environmental impact, decreasing substrate defects, etc.), to improve further on the target performance metrics, to adjust operation of a process chamber (e.g., in view of degradation or chamber aging), or the like.

Generation, optimization, and other adjustment of process recipes may include expending considerable effort. For example, one or more models may be generated and utilized for process recipe design, many test substrates may be manufactured for recipe design, etc. A manufacturing facility may benefit from having one or more process recipes conforming to best known methods for a target substrate design. For example, different designs of chambers may include different process recipes to achieve the same manufactured product design, substrate design, substrate function, substrate profile, environmental impact, energy or material expenditure, or the like. In other cases, process recipes may be customized based on components included in a process chamber. In still other cases, process recipes may be customized to a specific process chamber, e.g., to account for small differences between nominally identical chambers, e.g., due to differences in components within manufacturing tolerances.

Generating and maintaining process recipes for a large number of chambers, chamber types, combinations of chamber components, etc., may be difficult, expensive, and/or inconvenient. In particular, costs associated with introducing a new chamber, new component, or the like to a manufacturing facility (e.g., by purchasing a new chamber, repurposing a chamber for a particular process recipe, or the like) may be significant. New process recipe adjustments, new best known methods, new expert knowledge, new experimental data, new models, etc., may all be generated whenever a change to a set of chambers of a manufacturing facility is performed.

Generation of new process recipes, process recipe updates, or the like in connection with new process chambers or updates to process chambers may include costs associated with subject matter expert time, materials for experimental process operation performance, costs associated with disposing of substrates generated during experiments, costs associated with measuring properties of substrates and/or process conditions for determining effectiveness of recipes, etc. Further, such costs may be incurred repeatedly, as refining a process recipe may be an iterative process, including many repetitions of updating a process recipe, testing the updating recipe, and determining new updates based on the testing.

Methods and systems of the present disclosure may address one or more deficiencies of conventional methods. In some embodiments, one or more models are generated capturing operations of a first process chamber. The one or more models may be physics-based models. The one or more models may be data-based models, e.g., machine-learning or artificial intelligence models. The one or more models may include hybrid models, with aspects of data-based modeling and aspects of physics-based modeling. The one or more models may include rule-based, statistical, or heuristic models. The one or more models may include models of multiple types.

The models associated with the first process chamber may determine performance of the chamber, based on a set of inputs. For example, the inputs may include process inputs (e.g., process recipe, process knobs, etc.). The outputs may include some indication of performance of the process chamber. The inputs may include a single subsystem, multiple subsystems, or the like. Different models may be utilized for different subsystems, different sets of conditions, different combinations of input parameters, etc. For example, inputs may be or include power provided to various heating zones of the process chamber as part of a temperature determination system of the first process chamber. Other subsystems may include a gas flow subsystem, a plasma subsystem, or other subsystems that may be modeled and have an effect of substrate processing operations.

The output may include indications of substrate properties, such as substrate metrology, substrate performance, substrate defect density, substrate defect locations, substrate thickness, substrate thickness profile (e.g., a uniform profile, an M-shape profile, a W-shape profile, a uniform profile up to a particular radius (e.g., 120 mm) and an edge with a variance of up to 20% from the uniform profile, etc.), substrate film thickness, substrate composition, substrate reflectivity, refractive index, resistivity, substrate extinction coefficient, crystal quality, or other substrate properties. The output of the models associated with the first process chamber may include process conditions, such as temperature, gas composition, gas flow velocity, plasma properties, or the like present in the process chamber that may affect processing of a substrate. For example, the output may include processing conditions proximate a substrate support in the first process chamber.

Further models may be generated in connection with a second process chamber. The second process chamber may be of different design than the first process chamber. For example, the second process chamber may include different geometry, different components, different component control schemes, etc. In some embodiments, a number of controllable components may vary between the two process chambers, such as the second chamber being an updated chamber with more temperature control zones, more heater zones, and more temperature control knobs than the first chamber. In some embodiments, the number of controllable components may be the same, but control of those components may be different, such as controlling power provided to multiple components independently, or in a leader/follower arrangement. In some embodiments, the controllable components may be the same, but may be arranged to affect the second process chamber in a different way than the first process chamber, such as heaters or other components being disposed in different locations, various components being of different shape, size, or material construction, or the like which may adjust how controllable components determine conditions in the process chamber.

The models of the second process chamber may be utilized to determine process inputs based on target process performance parameters. For example, performance parameters output by models of the first process chamber may be utilized in connection with models of the second process chamber to determine process inputs corresponding to the performance parameters. In some embodiments, models associated with the second process chamber may receive as input target results of the second process chamber. For example, the models associated with the second process chamber may receive as input the indications of performance of the first process chamber which are generated as output by the models associated with the first process chamber. In some embodiments, target performance metrics (e.g., on-wafer metrics, target process conditions, target wafer design, etc.) may be used in combination with the models of the second process chamber to determine process inputs in connection with the second process chamber.

Models associated with the second process chamber may be inverted models, e.g., models that receive as input parameters that may conventionally be considered output (e.g., models may receive performance data as input, and generate process inputs predicted to result in the input performance data as output). Generation of models associated with the second process chamber may include inverting functional models, reversing operations of machine learning models, inverting one or more matrices representing functions of the model, or the like. In some embodiments, models may be utilized in an optimization manner to determine process inputs. For example, models may be utilized that receive process inputs and generate predicted performance data. Inputs may be adjusted in an iterative manner until target predicted performance data (e.g., within a threshold) is generated, and the input associated with that output may be utilized.

Process inputs generated in connection with the second process chamber may be utilized in generating a process recipe for execution by the second process chamber. Comparable results (e.g., in-chamber process conditions, on-wafer performance, or the like) to the best known methods in the first process chamber may be generated in the second process chamber by using the process inputs generated in connection with the second process chamber. Process recipes, process knob set values, process parameters, etc., may be transferred from the first process chamber to the second process chamber by utilizing methods described herein. Process recipes may be transferred or converted for the second process chamber, which may be of different design than the first process chamber, include one or more components that are different than the first process chamber, be nominally identical but have (e.g., unintentional) difference from the first chamber, or the like. In some embodiments, aspects of the present disclosure may be utilized in chamber matching operations. For example, performance of an acceptable chamber (e.g., a “golden chamber”) may be replicated by converting one or more aspects of a process recipe through methods described herein to be applied to one or more other process chambers.

In some embodiments, models associated with process chambers may be updated. For example, responsive to data collected during or in association with one or more process runs, one or more parameters of a model may be updated. Changes in a chamber performance due to chamber aging, chamber drift, chamber maintenance, seasoning, or cleaning operations, or the like, may be captured by updating parameters of one or more models based on measured data. Parameters of a physics-based model may be updated, one or more parameters of a data-based model may be updated, etc.

In some embodiments, performance of a process chamber (e.g., the second process chamber) may not match predictions. For example, on-wafer quantities may not meet predicted quantities based on the one or more models in association with the process chamber. Conventional methods may include consulting a subject matter expert for potential changes to a process recipe to reduce a difference between measured and predicted performance. Updating the process recipe may be a highly multi-dimensional problem, and reducing a difference between expected performance and measured performance may include many iterative steps, many variables, many adjustments to process knobs, etc., incurring significant cost to update the process recipe. In some embodiments, a difference between one or more target or predicted performance metrics and corresponding measured performance metrics may be provided to one or more models associated with the process chamber. The models may provide recommended updates to a process recipe, which may reduce a number of iterations for achieving target performance, reduce cost of implementing new best known methods, reduce costs associated with subject matter expertise, reduce a dimensionality of a search for process inputs that result in target chamber performance, etc.

In some embodiments, one or more substrate performance metrics may not be well modeled by conventional modeling techniques. For example, a model associated with a process chamber may successfully model a thickness profile of a substrate, but may not effectively model die-to-die or within-die nonuniformity of a semiconductor wafer. In some embodiments, matching additional performance metrics between a first chamber which is performing at an acceptable level (e.g., a “golden chamber”) and a second chamber may improve performance metrics which are not well-understood. For example, converting a recipe from a golden chamber to another chamber, including matching one or more process conditions, may increase a similarity between performance of the two chambers beyond what may be achieved by including on-substrate performance metrics alone.

Methods and systems of the present disclosure provide technological advantages over conventional solutions. Utilizing a recipe converter based on models associated with a first and second chamber may decrease time, costs, subject matter expertise, materials, environmental impact, energy and material expenditure, disposal of materials, etc., compared to generating a process recipe for the second chamber following a conventional iterative procedure. Best known methods for one process chamber may be transferred to another process chamber without incurring the costs of conventional methods. Recipe updates (e.g., to improve recipe performance) may proceed with the methods described herein with fewer iterations and less cost and impact than updating recipes in conventional systems.

In one aspect of the present disclosure, a method includes obtaining, from a first model associated with a first process chamber, first output. The first output includes one or more target performance metrics of the first process chamber. The method further includes providing, to a second model associated with a second process chamber, the one or more target performance metrics as input. The method further includes obtaining, from the second model, second output. The second output includes process parameters in association with the second process chamber. The process parameters are predicted to correspond with the one or more target performance metrics. The method further includes performing a corrective action in view of the second output.

In another aspect of the present disclosure, a non-transitory machine-readable storage medium stores instructions. The instructions, when executed by a processing or computing device, cause the processing device to perform operations of the methods described herein. In another aspect of the present disclosure, a system includes memory and a processor coupled to the memory. The processor is configured to perform methods described herein.

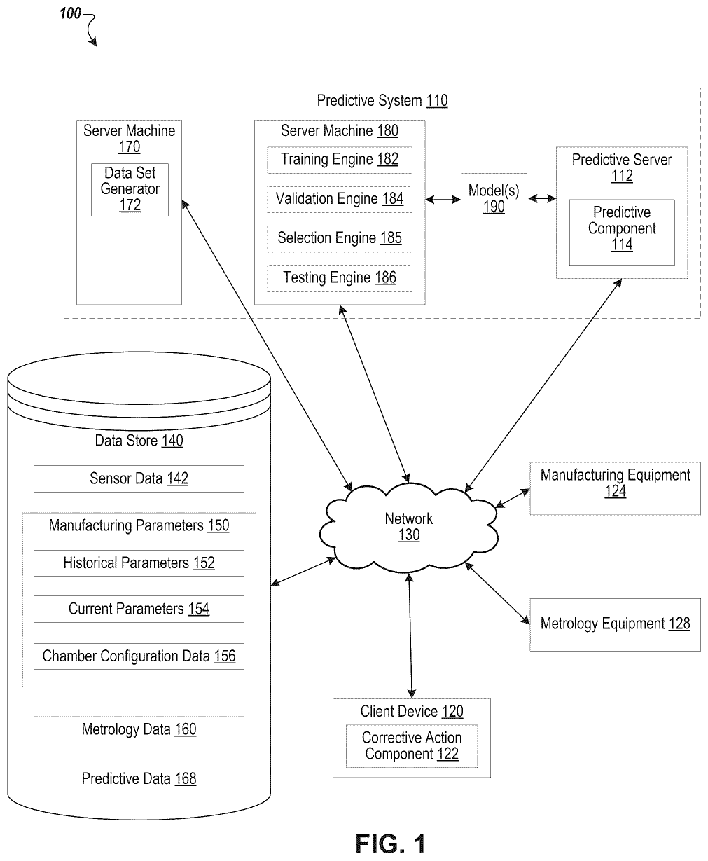

FIG. 1 is a block diagram illustrating an exemplary system 100 (exemplary system architecture), according to some embodiments. The system 100 includes a client device 120, manufacturing equipment 124, metrology equipment 128, predictive server 112, and data store 140. The predictive server 112 may be part of predictive system 110. Predictive system 110 may further include server machines 170 and 180.

Manufacturing equipment 124 may include one or more process tools, process chambers, or the like for performing processing operations to manufacture substrates. The operations may be for manufacturing, for example, NAND memory devices, random access memory (RAM) devices, 3D RAM devices, gate-all-around (GAA) transistors, and so on. Manufacturing equipment 124 may include multiple models or types of chambers configured to perform similar operations. For example, manufacturing equipment 124 may include multiple chambers with different configurations and/or different installed components, which are configured to manufacture products in the same manner. For example, multiple chambers may be used for epitaxy, for chemical vapor deposition, for physical vapor deposition, for atomic layer deposition, for etch, and so on. Substrates may have property values (film thickness, film strain, etc.) measured by metrology equipment 128. Metrology data 160 may be a component of data store 140. Metrology data 160 may include historical metrology data (e.g., metrology data associated with previously processed products). In some embodiments, historical metrology data may be used in training a machine leaning model, in calibrating a physics-based model, in generating a reduced-order model, or the like. Historical metrology data may be utilized in determining a historical likelihood of developing substrate defects, and the historical likelihood may be utilized in generating a machine learning model, in calibrating a physics-based model, in determining whether to use a model in association with a process of interest, or the like.

Metrology data 160 may be provided by instruments separate from a manufacturing mainframe, e.g., substrates may be measured at a standalone metrology facility. In some embodiments, metrology data 160 may be provided without use of a standalone metrology facility, e.g., in-situ metrology data (e.g., metrology or a proxy for metrology collected during processing), integrated metrology data (e.g., metrology or a proxy for metrology collected while a product is within a chamber or under vacuum, but not during processing operations), inline metrology data (e.g., data collected after a substrate is removed from vacuum), etc. Metrology data 160 may include current metrology data (e.g., metrology data associated with a product currently or recently processed). Current metrology data may be provided to update one or more models in association with defect root cause correction, e.g., by updating weights or biases of a machine learning model, updating parameters of a physics-based model, updating coefficients of a reduced order model, or the like

Data store 140 may further include sensor data 142. Sensor data 142 may include data generated by sensors of manufacturing equipment 124. Sensor data 142 may include data from multiple process chambers, multiple models of process chamber, chambers including multiple combinations of components, multiple types of process chambers (e.g., etch, deposition, anneal, etc.), or the like. Sensor data 142 may be indicative of process conditions within the process chamber(s) during processing of substrates. Sensor data 142 may include measured sensor data and virtual sensor data (e.g., sensor data predicted by one or more models). Sensor data 142 may be used for matching chamber performance, e.g., sensor data 142 may provide chamber conditions that may be matched between different chambers by some methods of the present disclosure. Sensor data 142 may include historical and current sensor data, e.g., for training of machine learning models, inference operations of machine learning models, etc.

Data store 140 may further include manufacturing parameters 150. Manufacturing parameters 150 may include parameters associated with performing substrate processing procedures, such as recipe data (e.g., process parameters), equipment constants (e.g., hardware parameters, parameters determining how operations of manufacturing equipment 124 are performed), indications of installed hardware components, or the like. Manufacturing parameter data, similar to metrology data 160, may include historical parameters 152 and current parameters 154. Historical parameters 152 may be utilized in generating a model (e.g., one or more models 190) for defect correction, e.g., to be used to reduce a likelihood of developing a particle defect during substrate processing. Current parameters 154 may be utilized in determining whether a process of interest is likely to generate substrate defects, e.g., by providing the current parameters 154 to model 190. Manufacturing parameters 150 may further include chamber configuration data 156. Chamber configuration data 156 may include data related to installed components, chamber models, or other chamber information related to multiple process chambers, e.g., for improving performance of one or more models in predicting manufacturing parameters for chamber matching operations.

In some embodiments metrology data 160, sensor data 142, and/or manufacturing parameters 150 may be processed (e.g., by the client device 120 and/or by the predictive server 112). Processing of the data may include generating features. In some embodiments, the features are a pattern in the metrology data 160, sensor data 142, and/or manufacturing parameters 150 (e.g., slope, width, height, peak, etc.) or a combination of values from the metrology data and/or manufacturing parameters (e.g., power derived from voltage and current, etc.). Manufacturing parameters 160 and sensor data 142 may include features and the features may be used by predictive component 114 for performing signal processing and/or for obtaining predictive data 168 for performance of a corrective action.

Each instance of metrology data 160, sensor data 142, and/or manufacturing parameters 150 may correspond to a product, a set of manufacturing equipment, a type of substrate produced by manufacturing equipment, or the like. A model 190 may also be associated with a particular product, substrate design, set of manufacturing equipment, design of manufacturing chamber, or the like. For example, a fluid dynamics model may be generated based on geometry of a type or design of process tool, a reduced order or machine learning model may be generated based on data from a particular design of chamber or a specific specimen of process chamber (e.g., to account for differences between nominally identical chambers), or the like. The data store may further store information associating sets of different data types, e.g. information indicative that a set of sensor data, a set of metrology data, and a set of manufacturing parameters are all associated with the same product, manufacturing equipment, type of substrate, etc.

In some embodiments, a processing device (e.g., via a model) may be used to generate predictive data 168. Predictive data 168 may include one or more indications of predicted improvements to a processing operation (e.g., to increase a similarity in processing procedure outputs between to chambers, to improve efficiency, to reduce gas backflow, to reduce a likelihood of generating particle defects on substrate, or the like). Predictive data 168 may be utilized by system 100 for performance of a corrective action (e.g., providing alerts to a user, updating process recipes, updating manufacturing parameters, scheduling maintenance, or the like).

In some embodiments, predictive system 110 may generate predictive data 168 utilizing a physics-based model. A physics-based model may include a mathematical representation of the laws of nature at play in the process chamber. The physics-based model may be a first principles model, an approximate model, or the like. The physics-based model may include a representation or parameterization of chamber geometry, pumping parameters, gas flow parameters, or the like. The physics-based model may be or include a gas flow model, a computational fluid dynamics model, a gas pressure model, a heat exchange model, an electrostatic model, a charged particle prediction model, a finite element analysis model, a spectral model, a finite difference model, a Monte Carlo simulation, a molecular dynamics model, a control volume model, or the like. Accordingly, methods such as computational fluid dynamics (CFD), finite element methods, spectral methods, finite difference, control volume, level-set, volume of fluid, Monte Carlo, molecular dynamics, etc. can be used to describe the governing physics (such as fluid flow, heat transfer, plasma chemistry/physics, ab initio, etc.) for the specific geometry and material properties of the system. A physics-based model may include one or more parameters that are allowed to be adjusted to fit the physics-based model to data, e.g., historical metrology data 164, e.g., to account for details of physics of the process chamber not captured by the original model parameters.

In some embodiments, predictive system 110 may generate predictive data 168 utilizing a reduced order model. A reduced order model may include a simplified version of a complex model (e.g., a simplified version of a computational fluid dynamics model). The reduced order model may mimic the performance of the full model under a target range of conditions (e.g., relevant to substrate processing conditions), while being more computationally efficient. Training data (e.g., historical metrology data 164, historical parameters 152, etc.) may be utilizing in determining which simplifications from a more complete model to make, in determining coefficients of a reduced order model, or the like.

In some embodiments, predictive system 110 may generate predictive data 168 utilizing one or more data-based models, e.g., machine learning or artificial intelligence models. The data-based models may be trained based on historical training data, including historical training input data and historical target output data. The data-based models may be provided current data (e.g., data associated with a process, chamber, or substrate of interest) to obtain output indicative of properties of the process, chamber, or substrate.

In some embodiments, predictive system 110 may generate predictive data 168 using a data driven model. A data driven model can be developed based on data through a statistical regression type of method, for example. The data may include statistical inferences based on historical process runs as well as probabilistic, heuristic, and/or knowledge-based insight. Data models include artificial intelligence (AI) and/or machine learning (ML) models in embodiments. In some embodiments, predictive system generates predictive data 168 using supervised machine learning (e.g., predictive data 168 includes output from a machine learning model that was trained using labeled data, such as manufacturing parameter data labelled with sensor data (e.g., which may correlate recipe set points to processing conditions in the chamber). In some embodiments, predictive system 110 may generate predictive data 168 using unsupervised machine learning (e.g., predictive data 168 includes output from a machine learning model that was trained using unlabeled data, output may include clustering results, principal component analysis, anomaly detection, etc.). In some embodiments, predictive system 110 may generate predictive data 168 using semi-supervised learning (e.g., training data may include a mix of labeled and unlabeled data, etc.).

Client device 120, manufacturing equipment 124, metrology equipment 128, predictive server 112, data store 140, server machine 170, and server machine 180 may be coupled to each other via network 130 for generating predictive data 168 to perform corrective actions. In some embodiments, network 130 may provide access to cloud-based services. Operations performed by client device 120, predictive system 110, data store 140, etc., may be performed by virtual cloud-based devices.

In some embodiments, network 130 is a public network that provides client device 120 with access to the predictive server 112, data store 140, and other publicly available computing devices. In some embodiments, network 130 is a private network that provides client device 120 access to manufacturing equipment 124, metrology equipment 128, data store 140, and other privately available computing devices. Network 130 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

Client device 120 may include computing devices such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, etc. Client device 120 may include a corrective action component 122. Corrective action component 122 may receive user input (e.g., via a Graphical User Interface (GUI) displayed via the client device 120) of an indication associated with manufacturing equipment 124. In some embodiments, corrective action component 122 transmits the indication to the predictive system 110, receives output (e.g., predictive data 168) from the predictive system 110, determines a corrective action based on the output, and causes the corrective action to be implemented. In some embodiments, corrective action component 122 obtains model input data associated with manufacturing equipment 124 (e.g., from data store 140, etc.) and provides the model input data (e.g., current parameters 154) associated with the manufacturing equipment 124 to predictive system 110.

In some embodiments, corrective action component 122 receives an indication of a corrective action from the predictive system 110 and causes the corrective action to be implemented. Each client device 120 may include an operating system that allows users to one or more of generate, view, or edit data (e.g., indication associated with manufacturing equipment 124, corrective actions associated with manufacturing equipment 124, etc.).

In some embodiments, metrology data 160 (e.g., historical metrology data) corresponds to historical property data of products (e.g., products processed using manufacturing parameters associated with historical manufacturing parameters 152) and predictive data 168 is associated with predicted property data (e.g., of products to be produced or that have been produced in conditions recorded by current manufacturing parameters 154). In some embodiments, predictive data 168 is or includes predicted metrology data (e.g., virtual metrology data, particle defect generation likelihood) of the products to be produced or that have been produced according to conditions recorded as current measurement data and/or current manufacturing parameters. Examples of metrology data include uniformity (e.g., of a film or layer), film quality, electrical resistance, conformality, surface roughness, and so on. Predictive data 168 may further include a predicted etch selectivity between two materials (e.g., between silicon etch and an oxide etch, or between silicon etch and a photoresist etch), a deposition rate, a etch rate, and so on. In some embodiments, predictive data 168 is or includes predictions of conditions in a process chamber in connection with current parameters 154, such as backflow conditions, pressure gradient conditions, temperature or plasma conditions, or the like generated in the process chamber. In some embodiments, predictive data 168 is or includes an indication of any abnormalities (e.g., abnormal products, abnormal components, abnormal manufacturing equipment 124, abnormal energy usage, etc.) and optionally one or more causes of the abnormalities. In some embodiments, predictive data 168 is an indication of change over time or drift in some component of manufacturing equipment 124, metrology equipment 128, and the like. In some embodiments, predictive data 168 is an indication of an end of life of a component of manufacturing equipment 124, metrology equipment 128, or the like.

Performing manufacturing processes that result in defective products can be costly in time, energy, products, components, manufacturing equipment 124, the cost of identifying the defects and discarding the defective product, etc. By inputting manufacturing parameters that are being used or are to be used to manufacture a product into predictive system 110, receiving output of predictive data 168, and performing a corrective action based on the predictive data 168, system 100 can have the technical advantage of avoiding the cost of producing, identifying, and discarding defective products.

Performing manufacturing processes that result in failure of the components of the manufacturing equipment 124 can be costly in downtime, damage to products, damage to equipment, express ordering replacement components, etc. By inputting manufacturing parameters that are being used or are to be used to manufacture a product, metrology data, measurement data, etc., receiving output of predictive data 168, and performing corrective action (e.g., predicted operational maintenance, such as replacement, processing, cleaning, etc. of components causing particles to be deposited on substrates during processing) based on the predictive data 168, system 100 can have the technical advantage of avoiding the cost of one or more of unexpected component failure, unscheduled downtime, productivity loss, unexpected equipment failure, product scrap, or the like. Monitoring the performance over time of components, e.g. manufacturing equipment 124, metrology equipment 128, and the like, may provide indications of degrading components.

Manufacturing parameters may be suboptimal for producing product which may have costly results of increased resource (e.g., energy, coolant, gases, etc.) consumption, increased amount of time to produce the products, increased component failure, increased amounts of defective products, etc. By inputting indications of manufacturing parameters 160 into a model 190, receiving an output of predictive data 168, and performing a corrective action of updating manufacturing parameters (e.g., setting optimal manufacturing parameters, updating a process recipe, or the like), system 100 can have the technical advantage of using optimal manufacturing parameters (e.g., hardware parameters, process parameters, optimal design) to avoid costly results of suboptimal manufacturing parameters, including improving a similarity between the performance of a chamber that is meeting performance thresholds, and a second chamber.

In some embodiments, the corrective action includes providing an alert (e.g., an alarm to stop or not perform the manufacturing process if the predictive data 168 indicates a predicted abnormality, such as an abnormality of the product, a component, or manufacturing equipment 124). In some embodiments, performance of the corrective action includes causing updates to one or more manufacturing parameters. In some embodiments, performance of a corrective action may include recalibration or adjustment of parameters of a physics-based model or reduced order model. In some embodiments performance of a corrective action may include retraining a machine learning model associated with manufacturing equipment 124. In some embodiments, performance of a corrective action may include training a new machine learning model associated with manufacturing equipment 124.

Manufacturing parameters 150 may include hardware parameters (e.g., information indicative of which components are installed in manufacturing equipment 124, indicative of component replacements, indicative of component age, indicative of software version or updates, etc.) and/or process parameters (e.g., temperature, pressure, flow, rate, electrical current, voltage, gas flow, lift speed, amount and/or ratio of precursor chemicals, etc.). In some embodiments, the corrective action includes causing preventative operative maintenance (e.g., replace, process, clean, etc. components of the manufacturing equipment 124). In some embodiments, the corrective action includes causing design optimization (e.g., updating manufacturing parameters, manufacturing processes, manufacturing equipment 124, etc. for an optimized product). In some embodiments, the corrective action includes a updating a recipe (e.g., altering the timing of manufacturing subsystems entering an idle or active mode, altering set points of various property values, etc.). In some embodiments, a corrective action includes updating a duration of one or more processing actions, such as opening or closing a valve, adjusting a flow meter, or the like. A corrective action may include introducing or adjusting a ramp time for actuating a valve, adjusting operation of a component, or the like.

Predictive server 112, server machine 170, and server machine 180 may each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc. Operations of predictive server 112, server machine 170, server machine 180, data store 140, etc., may be performed by a cloud computing service, cloud data storage service, etc.

Predictive server 112 may include a predictive component 114. In some embodiments, the predictive component 114 may receive current manufacturing parameters (e.g., receive from the client device 120, retrieve from the data store 140) and generate output (e.g., predictive data 168) for performing corrective action associated with the manufacturing equipment 124 based on the current data. In some embodiments, predictive data 168 may include one or more predicted defects of a processed product. In some embodiments, predictive data 168 may include predicted manufacturing parameters for a second chamber to match chamber conditions during processing to conditions of a first chamber. In some embodiments, predictive component 114 may use one or more trained machine learning models 190 to determine the output for performing the corrective action based on current data.

Manufacturing equipment 124 may be associated with one or more models, e.g., model 190. In some embodiments, model(s) 190 may be or include physics-based models, reduced order models, machine learning models, etc. Machine learning models associated with manufacturing equipment 124 may perform many tasks, including process control, classification, performance predictions, etc. Model 190 may be trained using data associated with manufacturing equipment 124 or products processed by manufacturing equipment 124, e.g., sensor data 142, manufacturing parameters 150 (e.g., associated with process control of manufacturing equipment 124), metrology data 160 (e.g., generated by metrology equipment 128), etc.

One type of machine learning model that may be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs).

A recurrent neural network (RNN) is another type of machine learning model. A recurrent neural network model is designed to interpret a series of inputs where inputs are intrinsically related to one another, e.g., time trace data, sequential data, etc. Output of a perceptron of an RNN is fed back into the perceptron as input, to generate the next output.

Deep learning is a class of machine learning algorithms that use a cascade of multiple layers of nonlinear processing units for feature extraction and transformation. Each successive layer uses the output from the previous layer as input. Deep neural networks may learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. In an image recognition application, for example, the raw input may be a matrix of pixels; the first representational layer may abstract the pixels and encode edges; the second layer may compose and encode arrangements of edges; the third layer may encode higher level shapes (e.g., teeth, lips, gums, etc.); and the fourth layer may recognize a scanning role. Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs may be that of the network and may be the number of hidden layers plus one. For recurrent neural networks, in which a signal may propagate through a layer more than once, the CAP depth is potentially unlimited.

In some embodiments, predictive component 114 obtains current manufacturing parameters 154 and/or sensor data 142, performs signal processing to break down the current data into sets of current data, provides the sets of current data as input to a trained model 190, and obtains outputs indicative of predictive data 168 from the trained model 190. In some embodiments, predictive component 114 receives metrology data (e.g., predicted defect formation likelihood) of a substrate and provides the metrology data to trained model 190. Model 190 may be configured to accept data indicative of manufacturing parameters and generate as predictions of associated chamber conditions and/or predictions of associated manufacturing parameters to produce the chamber conditions. In some embodiments, predictive data is indicative of metrology data (e.g., prediction of substrate quality, substate defect likelihood, or the like). In some embodiments, predictive data is indicative of manufacturing equipment health (e.g., an indication of a component or components likely to be contributing to substrate defects).

In some embodiments, the various models discussed in connection with model 190 (e.g., supervised machine learning model, unsupervised machine learning model, etc.) may be combined in one model (e.g., an ensemble model), or may be separate models.

Data store 140 may be a memory (e.g., random access memory), a drive (e.g., a hard drive, a flash drive), a database system, a cloud-accessible memory system, or another type of component or device capable of storing data. Data store 140 may include multiple storage components (e.g., multiple drives or multiple databases) that may span multiple computing devices (e.g., multiple server computers). The data store 140 may store sensor data 142, manufacturing parameters 150, metrology data 160, and predictive data 168.

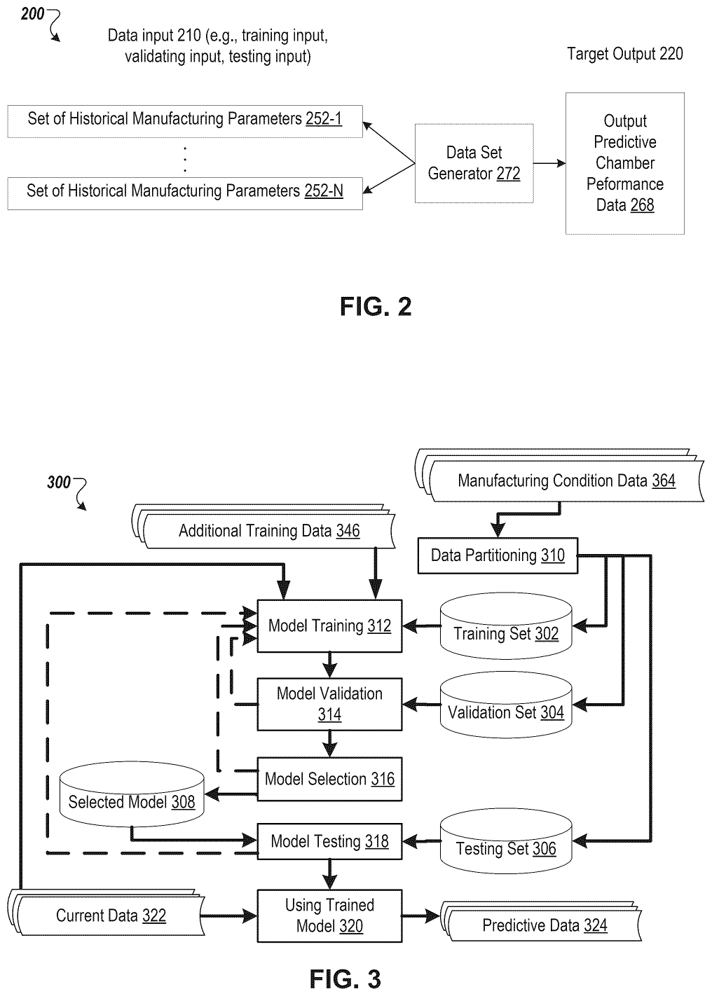

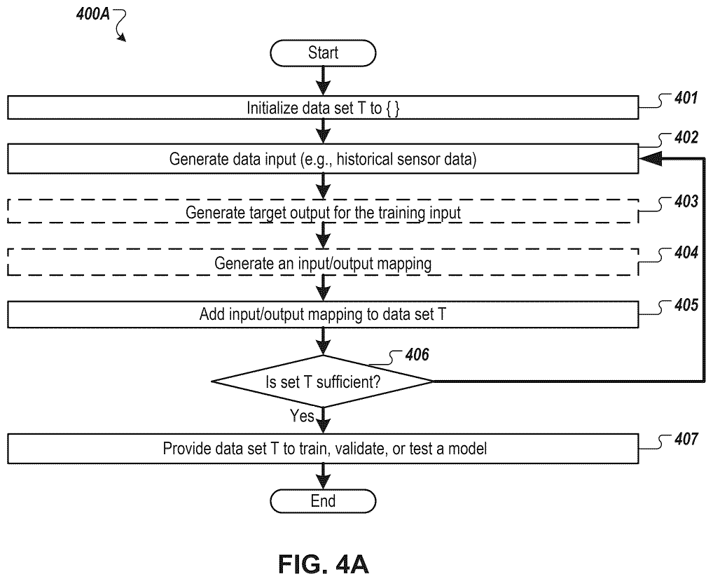

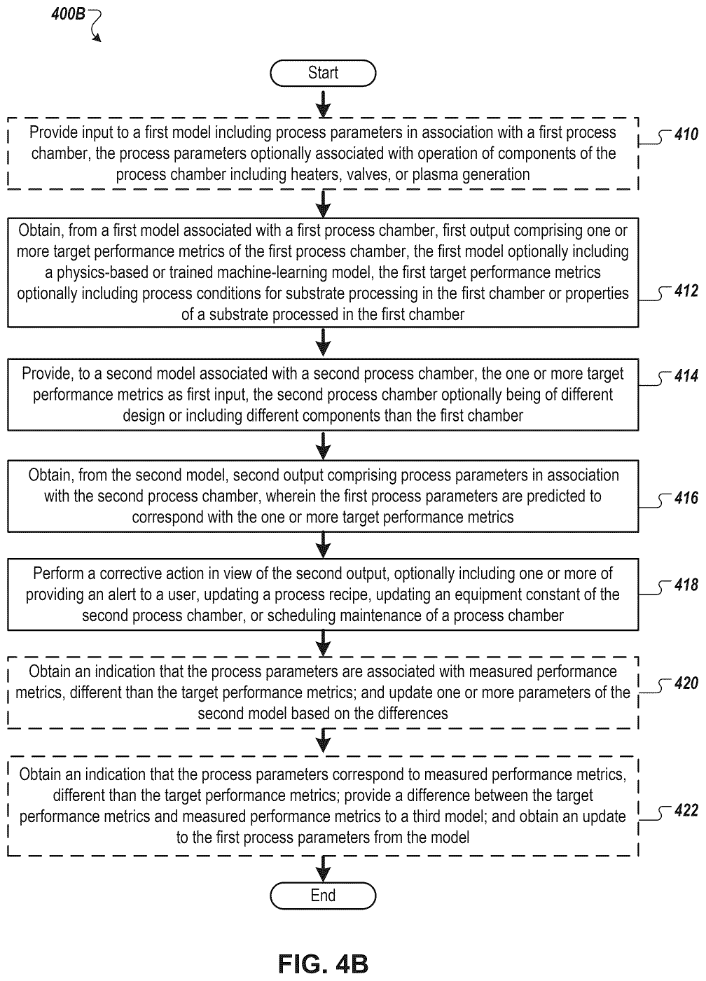

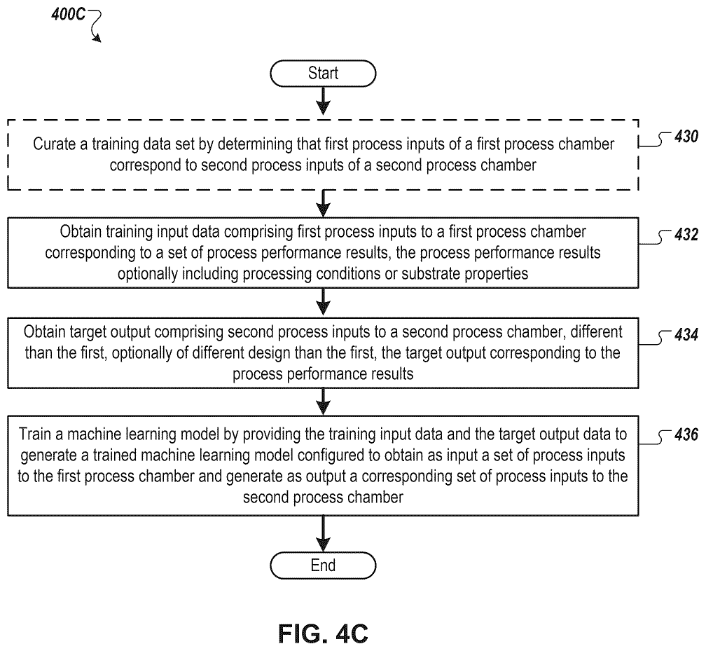

In some embodiments, predictive system 110 further includes server machine 170 and server machine 180. Server machine 170 includes a data set generator 172 that is capable of generating data sets (e.g., a set of data inputs and a set of target outputs) to train, validate, and/or test model(s) 190, including one or more machine learning models. Some operations of data set generator 172 are described in detail below with respect to FIGS. 2 and 4A. In some embodiments, data set generator 172 may partition the historical data (e.g., historical manufacturing parameters 152, historical metrology data 164) into a training set (e.g., sixty percent of the historical data), a validating set (e.g., twenty percent of the historical data), and a testing set (e.g., twenty percent of the historical data).

Server machine 180 includes a training engine 182, a validation engine 184, selection engine 185, and/or a testing engine 186. An engine (e.g., training engine 182, a validation engine 184, selection engine 185, and a testing engine 186) may refer to hardware (e.g., circuitry, dedicated logic, programmable logic, microcode, processing device, etc.), software (such as instructions run on a processing device, a general purpose computer system, or a dedicated machine), firmware, microcode, or a combination thereof. The training engine 182 may be capable of training a model 190 using one or more sets of features associated with the training set from data set generator 172. The training engine 182 may generate multiple trained models 190, where each trained model 190 corresponds to a distinct set of features of the training set. For example, a first trained model may have been trained using all features (e.g., X1-X5), a second trained model may have been trained using a first subset of the features (e.g., X1, X2, X4), and a third trained model may have been trained using a second subset of the features (e.g., X1, X3, X4, and X5) that may partially overlap the first subset of features. Data set generator 172 may receive the output of a trained, collect that data into training, validation, and testing data sets, and use the data sets to train a second model (e.g., a machine learning model configured to output predictive data, corrective actions, etc.).

Validation engine 184 may be capable of validating a trained model 190 using a corresponding set of features of the validation set from data set generator 172. For example, a first trained machine learning model 190 that was trained using a first set of features of the training set may be validated using the first set of features of the validation set. The validation engine 184 may determine an accuracy of each of the trained models 190 based on the corresponding sets of features of the validation set. Validation engine 184 may discard trained models 190 that have an accuracy that does not meet a threshold accuracy. In some embodiments, selection engine 185 may be capable of selecting one or more trained models 190 that have an accuracy that meets a threshold accuracy. In some embodiments, selection engine 185 may be capable of selecting the trained model 190 that has the highest accuracy of the trained models 190.

Testing engine 186 may be capable of testing a trained model 190 using a corresponding set of features of a testing set from data set generator 172. For example, a first trained machine learning model 190 that was trained using a first set of features of the training set may be tested using the first set of features of the testing set. Testing engine 186 may determine a trained model 190 that has the highest accuracy of all of the trained models based on the testing sets.

In the case of a machine learning model, model 190 may refer to the model artifact that is created by training engine 182 using a training set that includes data inputs and corresponding target outputs (correct answers for respective training inputs. Patterns in the data sets can be found that map the data input to the target output (the correct answer), and machine learning model 190 is provided mappings that capture these patterns. The machine learning model 190 may use one or more of Support Vector Machine (SVM), Radial Basis Function (RBF), clustering, supervised machine learning, semi-supervised machine learning, unsupervised machine learning, k-Nearest Neighbor algorithm (k-NN), linear regression, random forest, neural network (e.g., artificial neural network, recurrent neural network), etc. In some embodiments, one or more machine learning models 190 may be trained using historical data (e.g., historical parameters 152).

Predictive component 114 may provide current data to model 190 and may run model 190 on the input to obtain one or more outputs. For example, predictive component 114 may provide current parameters 154 to model 190 and may run model 190 on the input to obtain one or more outputs. Predictive component 114 may be capable of determining (e.g., extracting) predictive data 168 from the output of model 190. Predictive component 114 may determine (e.g., extract) confidence data from the output that indicates a level of confidence that predictive data 168 is an accurate predictor of a process associated with the input data for products produced or to be produced using the manufacturing equipment 124 at the current manufacturing parameters. Predictive component 114 or corrective action component 122 may use the confidence data to decide whether to cause a corrective action associated with the manufacturing equipment 124 based on predictive data 168.

The confidence data may include or indicate a level of confidence that the predictive data 168 is an accurate prediction for products or components associated with at least a portion of the input data. In one example, the level of confidence is a real number between 0 and 1 inclusive, where 0 indicates no confidence that the predictive data 168 is an accurate prediction for products processed according to input data or component health of components of manufacturing equipment 124 and 1 indicates absolute confidence that the predictive data 168 accurately predicts properties of products processed according to input data or component health of components of manufacturing equipment 124. Responsive to the confidence data indicating a level of confidence below a threshold level for a predetermined number of instances (e.g., percentage of instances, frequency of instances, total number of instances, etc.) predictive component 114 may cause trained model 190 to be re-trained (e.g., based on current manufacturing parameters, current metrology, measurements of conditions in the chamber, etc.). In some embodiments, retraining may include generating one or more data sets (e.g., via data set generator 172) utilizing historical data.

For purpose of illustration, rather than limitation, aspects of the disclosure describe the training of one or more machine learning models 190 using historical data (e.g., historical metrology data, historical manufacturing parameters 152, historical sensor data) and inputting current data (e.g., current manufacturing parameters, and current metrology data) into the one or more trained machine learning models to determine predictive data 168. In other embodiments, a heuristic model, physics-based model, or rule-based model is used to determine predictive data 168 (e.g., without using a trained machine learning model). In some embodiments, such models may be trained using historical data. In some embodiments, these models may be retrained utilizing a historical data and/or current data. Predictive component 114 may monitor historical manufacturing parameters, and metrology data 160. Any of the information described with respect to data inputs 210 of FIG. 2 may be monitored or otherwise used in the heuristic, physics-based, or rule-based model.

In some embodiments, the functions of client device 120, predictive server 112, server machine 170, and server machine 180 may be provided by a fewer number of machines. For example, in some embodiments server machines 170 and 180 may be integrated into a single machine, while in some other embodiments, server machine 170, server machine 180, and predictive server 112 may be integrated into a single machine. In some embodiments, client device 120 and predictive server 112 may be integrated into a single machine. In some embodiments, functions of client device 120, predictive server 112, server machine 170, server machine 180, and data store 140 may be performed by a cloud-based service.

In general, functions described in one embodiment as being performed by client device 120, predictive server 112, server machine 170, and server machine 180 can also be performed on predictive server 112 in other embodiments, if appropriate. In addition, the functionality attributed to a particular component can be performed by different or multiple components operating together. For example, in some embodiments, the predictive server 112 may determine the corrective action based on the predictive data 168. In another example, client device 120 may determine the predictive data 168 based on output from the trained machine learning model.

In addition, the functions of a particular component can be performed by different or multiple components operating together. One or more of the predictive server 112, server machine 170, or server machine 180 may be accessed as a service provided to other systems or devices through appropriate application programming interfaces (API).

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

FIG. 2 depicts a block diagram of example data set generator 272 (e.g., data set generator 172 of FIG. 1) to create data sets for training, testing, validating, calibrating, etc. a model (e.g., model 190 of FIG. 1), according to some embodiments. Each data set generator 272 may be part of server machine 170 of FIG. 1. In some embodiments, data set generator 272 may generate data sets to be utilized to adjust, validate, test, or the like a physics-based model or reduced order model. In some embodiments, data set generator 272 may generate data sets to be utilized in generating, validating, etc., machine learning models in association with the manufacturing equipment. In some embodiments, several models associated with manufacturing equipment 124 may be trained, used, and maintained (e.g., within a manufacturing facility). One or more physics-based models, one or more reduced order models, and/or one or more trained machine learning models may be generated and maintained in association with the manufacturing equipment. Each model may be associated with one data set generators 272, multiple models may share a data set generator 272, etc.

FIG. 2 depicts a system 200 including data set generator 272 for creating data sets for one or more supervised models (e.g., including data associated with input to a model and output from the model). Data set generator 272 may create data sets (e.g., data input 210, target output 220) using historical data, which may include manufacturing parameters, chamber condition data, substrate property data, or the like. In some embodiments, a data set generator similar to data set generator 272 may be utilized to train an unsupervised model, e.g., target output 220 may not be generated by data set generator 272.

Data set generator 272 may generate data sets to train, test, and validate a model, e.g., a machine learning model. Data set generator 272 may generate data sets to calibrate a model, e.g., a physics-based model (including reduced order models). In some embodiments, data set generator 272 may generate data sets for a machine learning model. In some embodiments, data set generator 272 may generate data sets for training, testing, and/or validating a model configured to predict defect generation data in a substrate processing system, such as generating data indicating predicted chamber performance, predicted chamber matching parameters, a recommended update to substrate processing, or the like.

A model to be generated (e.g., trained, calibrated, or the like) may be provided with a set of historical manufacturing parameters 252-1 as data input 210. The set of historical manufacturing parameters 252-1 may include process control set points. The set of historical manufacturing parameters 252-1 may include parameters determining actions of manufacturing equipment, such as ramp times for valve actuation. The model may be configured to accept indications of manufacturing parameters (e.g., current manufacturing parameters) as input and generate predictions related to particle defect generation as output.

Data set generator 272 may be used to generate data sets for any type of model used in association with predicting or correcting process chamber performance (e.g., processing conditions, on-substrate outcomes, etc.). Data set generator 272 may be used to generate data for any type of machine learning model that takes as input historical manufacturing parameter data. In some embodiments, an analogous data set generator may be used to generate data for a machine learning model that instead or additionally takes as input historical sensor data, e.g., to be used for matching chamber conditions of a second chamber to measured conditions expressed in the historical sensor data. Data set generator 272 may be used to generate data for a machine learning model that generates predicted chamber performance data, such as predicted on-substrate outcomes, predicted chamber processing conditions, or the like. Data set generator 272 may be used to generate data for a machine learning model configured to provide process update instructions, e.g., configured to update manufacturing parameters, manufacturing recipes, equipment constants, or the like. Data set generator 272 may be used to generate data for a machine learning model configured to identify a product anomaly and/or processing equipment fault.

In some embodiments, data set generator 272 generates a data set (e.g., training set, validating set, testing set) that includes one or more data inputs 210 (e.g., training input, validating input, testing input). Data inputs 210 may be provided to training engine 182, validating engine 184, or testing engine 186. The data set may be used to train, validate, or test the model (e.g., model 190 of FIG. 1).

In some embodiments, data input 210 may include one or more sets of data. As an example, system 200 may produce sets of manufacturing parameter data that may include one or more of parameter data from one or more types of components, combinations of parameter data from one or more types of components, patterns from parameter data from one or more types of components, or the like. In some embodiments, target output 220 may include sets of output related to the various sets of data input 210.

In some embodiments, data set generator 272 may generate a first data input corresponding to a first set of manufacturing parameters 252-1 to train, validate, or test a first machine learning model. Data set generator 272 may generate a second data input corresponding to a second set of historical manufacturing parameter data (e.g., a set of historical metrology data 252-2, not shown) to train, validate, or test a second machine learning model. Further sets of historical data may further be utilized in generating further machine learning models. Any number of sets of historical data may be utilized in generating any number of machine learning models, up to a final set, set of historical manufacturing parameters 252-N (N representing any target quantity of data sets, models, etc.)

In some embodiments, data set generator 272 may generate a first data input corresponding to a first set of historical manufacturing parameters 252-1 to train, validate, or test a first machine learning model. Data set generator 272 may generate a second data input corresponding to a second set of historical manufacturing parameters 252-2 (not shown) to train, validate, or test a second machine learning model.

In some embodiments, data set generator 272 generates a data set (e.g., training set, validating set, testing set) that includes one or more data inputs 210 (e.g., training input, validating input, testing input) and may include one or more target outputs 220 that correspond to the data inputs 210. The data set may also include mapping data that maps the data inputs 210 to the target outputs 220. In some embodiments, data set generator 272 may generate data for training a model configured to output relevant to preventing particle defect formation, by generating data sets including output predictive chamber performance data 268. Data inputs 210 may also be referred to as “features,” “attributes,” or “information.” In some embodiments, data set generator 272 may provide the data set to training engine 182, validating engine 184, or testing engine 186, where the data set is used to train, validate, or test the model (e.g., one of the machine learning models that are included in model 190, ensemble model 190, etc.).

In some embodiments, an analogous data set generator to data set generator 272 may be used to generate training data for a model that is configured to perform an inverse operation of the operations performed by a model trained by data set generator 272. For example, a model may obtain as input chamber performance data (e.g., chamber conditions data, substrate outcome data, etc.) and be trained to generate output that is analogous to the training input data of data set generator 272 (e.g., manufacturing data). An operation including both converting manufacturing parameters of one chamber to chamber output data, and providing the chamber output data to an inverse model to obtain predicted manufacturing parameters for a second chamber associated with the chamber output data, may be used for chamber matching operations in accordance with methods of the present disclosure.

In some embodiments, subsequent to generating a data set and training, validating, or testing a machine learning model using the data set, the model may be further trained, validated, or tested, or adjusted (e.g., adjusting weights or parameters associated with input data of the model, such as connection weights in a neural network).

FIG. 3 is a block diagram illustrating system 300 for generating output data (e.g., predictive data 168 of FIG. 1), according to some embodiments. In some embodiments, system 300 may be used in conjunction with a model (e.g., physics-based, reduced order, data-based, machine learning, or the like) configured to generate predictive data related to matching chamber performance between multiple process chambers, including processing conditions and/or product properties. In some embodiments, system 300 is utilized for generating output data by a model such as model 190 of FIG. 1. In some embodiments, system 300 may be used in conjunction with a model to determine a corrective action associated with manufacturing equipment. In some embodiments, system 300 may be used in conjunction with a model to determine a fault of manufacturing equipment, e.g., a component resulting in particles being deposited on substrates during processing operations. In some embodiments, system 300 may be used in conjunction with a machine learning model to cluster or classify substrates or substrate defects. System 300 may be used in conjunction with a machine learning model with a different function than those listed, associated with a manufacturing system.

At block 310, system 300 (e.g., components of predictive system 110 of FIG. 1) performs data partitioning (e.g., via data set generator 172 of server machine 170 of FIG. 1) of data to be used in training, validating, and/or testing a model, such as a machine learning model. Manufacturing condition data 364 may be provided as training data, and may include training input and target output data. Manufacturing condition data 364 may include multiple categories of data related to manufacturing, such as recipe set points, target process conditions, measured process conditions, equipment constants, operative parameters (e.g., power provided to one or more components, valve opening values, plasma power frequency, etc.). Manufacturing condition data 364 may include process conditions and parameters that effect or determine those process conditions.

In some embodiments, manufacturing condition data 364 includes historical data, such as historical metrology data (e.g., particle defect generation rates), historical manufacturing parameter data, historical classification data (e.g., classification of substrate properties or defects), measured or simulated chamber condition data (e.g., processing conditions within a chamber during processing operations), etc. In some embodiments, e.g., when utilizing physics-based model data to train a machine learning model, manufacturing condition data 364 may include data output by a physics-based model (e.g., a virtual sensor model). Manufacturing condition data 364 may undergo data partitioning at block 310 to generate training set 302, validation set 304, and testing set 306. For example, the training set may be 60% of the training data, the validation set may be 20% of the training data, and the testing set may be 20% of the training data.

The generation of training set 302, validation set 304, and testing set 306 may be tailored for a particular application. For example, the training set may be 60% of the training data, the validation set may be 20% of the training data, and the testing set may be 20% of the training data. System 300 may generate a plurality of sets of features for each of the training set, the validation set, and the testing set. For example, if manufacturing condition data 364 includes manufacturing parameters, including features derived from 20 recipe parameters and 10 hardware parameters, the data may be divided into a first set of features including recipe parameters 1-10 and a second set of features including recipe parameters 11-20. The hardware parameters may also be divided into sets, for instance a first set of hardware parameters including parameters 1-5, and a second set of hardware parameters including parameters 6-10. Either target input, target output, both, or neither may be divided into sets. Multiple models may be trained on different sets of data.

At block 312, system 300 performs model training (e.g., via training engine 182 of FIG. 1) using training set 302. Training of a machine learning model and/or of a physics-based model (e.g., a digital twin) may be achieved in a supervised learning manner, which involves providing a training dataset including labeled inputs through the model, observing its outputs, defining an error (by measuring the difference between the outputs and the label values), and using techniques such as deep gradient descent and backpropagation to tune the weights of the model such that the error is minimized. In many applications, repeating this process across the many labeled inputs in the training dataset yields a model that can produce correct output when presented with inputs that are different than the ones present in the training dataset. In some embodiments, training of a machine learning model may be achieved in an unsupervised manner, e.g., labels or classifications may not be supplied during training. An unsupervised model may be configured to perform anomaly detection, result clustering, etc.

For each training data item in the training dataset, the training data item may be input into the model (e.g., into the machine learning model). The model may then process the input training data item (e.g., one or more manufacturing parameter values, etc.) to generate an output. The output may include, for example, a prediction of processing conditions related to process inputs. The output may be compared to a label of the training data item (e.g., measured or simulated sensor data related to processing conditions). In some embodiments, a model configured to perform the inverse of this operation may be trained, e.g., a model that obtains process conditions as input and produces predictive process parameters as output.

Processing logic may then compare the generated output (e.g., predicted process input data) to the label (e.g., actual process input data) that was included in the training data item. Processing logic determines an error (i.e., a classification error) based on the differences between the output and the label(s). Processing logic adjusts one or more weights and/or values of the model based on the error.

In the case of training a neural network, an error term or delta may be determined for each node in the artificial neural network. Based on this error, the artificial neural network adjusts one or more of its parameters for one or more of its nodes (the weights for one or more inputs of a node). Parameters may be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters may include adjusting the weights assigned to each of the inputs for one or more neurons at one or more layers in the artificial neural network.

System 300 may train multiple models using multiple sets of features of the training set 302 (e.g., a first set of features of the training set 302, a second set of features of the training set 302, etc.). For example, system 300 may train a model to generate a first trained model using the first set of features in the training set (e.g., manufacturing parameter data from components 1-10, condition predictions 1-10, etc.) and to generate a second trained model using the second set of features in the training set (e.g., manufacturing parameter data from components 11-20, modeling process chamber conditions 11-20, etc.). In some embodiments, the first trained model and the second trained model may be combined to generate a third trained model (e.g., which may be a better predictor than the first or the second trained model on its own). In some embodiments, sets of features used in comparing models may overlap (e.g., first set of features being parameters 1-15 and second set of features being parameters 5-20). In some embodiments, hundreds of models may be generated including models with various permutations of features and combinations of models.

At block 314, system 300 performs model validation (e.g., via validation engine 184 of FIG. 1) using the validation set 304. The system 300 may validate each of the trained models using a corresponding set of features of the validation set 304. For example, system 300 may validate the first trained model using the first set of features in the validation set (e.g., parameters 1-10 or conditions 1-10) and the second trained model using the second set of features in the validation set (e.g., parameters 11-20 or conditions 11-20). In some embodiments, system 300 may validate hundreds of models (e.g., models with various permutations of features, combinations of models, etc.) generated at block 312. At block 314, system 300 may determine an accuracy of each of the one or more trained models (e.g., via model validation) and may determine whether one or more of the trained models has an accuracy that meets a threshold accuracy. Responsive to determining that none of the trained models has an accuracy that meets a threshold accuracy, flow returns to block 312 where the system 300 performs model training using different sets of features of the training set. Responsive to determining that one or more of the trained models has an accuracy that meets a threshold accuracy, flow continues to block 316. System 300 may discard the trained models that have an accuracy that is below the threshold accuracy (e.g., based on the validation set).

At block 316, system 300 performs model selection (e.g., via selection engine 185 of FIG. 1) to determine which of the one or more trained models that meet the threshold accuracy has the highest accuracy (e.g., the selected model 308, based on the validating of block 314). Responsive to determining that two or more of the trained models that meet the threshold accuracy have the same accuracy, flow may return to block 312 where the system 300 performs model training using further refined training sets corresponding to further refined sets of features for determining a trained model that has the highest accuracy.

At block 318, system 300 performs model testing (e.g., via testing engine 186 of FIG. 1) using testing set 306 to test selected model 308. System 300 may test, using the first set of features in the testing set (e.g., parameters 1-10), the first trained model to determine the first trained model meets a threshold accuracy. Determining whether the first trained model meets a threshold accuracy may be based on the first set of features of testing set 306. Responsive to accuracy of the selected model 308 not meeting the threshold accuracy, flow continues to block 312 where system 300 performs model training (e.g., retraining) using different training sets corresponding to different sets of features. Accuracy of selected model 308 may not meet threshold accuracy if selected model 308 is overly fit to the training set 302 and/or validation set 304. Accuracy of selected model 308 may not meet threshold accuracy if selected model 308 is not applicable to other data sets, including testing set 306. Training using different features may include training using data from different sensors, different manufacturing parameters, etc. Responsive to determining that selected model 308 has an accuracy that meets a threshold accuracy based on testing set 306, flow continues to block 320. In at least block 312, the model may learn patterns in the training data to make predictions. In block 318, the system 300 may apply the model on the remaining data (e.g., testing set 306) to test the predictions.

At block 320, system 300 uses the trained model (e.g., selected model 308) to receive current data 322 and determines (e.g., extracts), from the output of the trained model, predictive data 324. Current data 322 may be manufacturing parameters related to a process, operation, or action of interest. Current data 322 may be manufacturing parameters related to a process under development, redevelopment, investigation, etc. Current data 322 may be manufacturing parameters related to a chamber being used in production or expected to be placed into production. A corrective action associated with the manufacturing equipment 124 of FIG. 1 may be performed in view of predictive data 324. In some embodiments, current data 322 may correspond to the same types of features in the historical data used to train the machine learning model. In some embodiments, current data 322 corresponds to a subset of the types of features in historical data that are used to train selected model 308. For example, a machine learning model may be trained using a number of manufacturing parameters, and configured to generate output based on a subset of the manufacturing parameters.

In some embodiments, the performance of a machine learning model trained, validated, and tested by system 300 may deteriorate. For example, a manufacturing system associated with the trained machine learning model may undergo a gradual change or a sudden change. A change in the manufacturing system may result in decreased performance of the trained machine learning model. A new model may be generated to replace the machine learning model with decreased performance. The new model may be generated by altering the old model by retraining, by generating a new model, etc.

Generation of a new model may include providing additional training data 346. Generation of a new model may further include providing current data 322, e.g., data that has been used by the model to make predictions. In some embodiments, current data 322 when provided for generation of a new model may be labeled with an indication of an accuracy of predictions generated by the model based on current data 322. Additional training data 346 may be provided to model training 312 for generation of one or more new machine learning models, updating, retraining, and/or refining of selected model 308, etc.

In some embodiments, one or more of the acts 310-320 may occur in various orders and/or with other acts not presented and described herein. In some embodiments, one or more of acts 310-320 may not be performed. For example, in some embodiments, one or more of data partitioning of block 310, model validation of block 314, model selection of block 316, or model testing of block 318 may not be performed.

FIG. 3 depicts a system configured for training, validating, testing, and using one or more machine learning models. The machine learning models are configured to accept data as input (e.g., set points provided to manufacturing equipment, sensor data, metrology data, etc.) and provide data as output (e.g., predictive data, corrective action data, classification data, etc.). Partitioning, training, validating, selection, testing, and using blocks of system 300 may be executed similarly to train a second model, utilizing different types of data. Retraining may also be performed, utilizing current data 322 and/or additional training data 346.

FIGS. 4A-C are flow diagrams of methods 400A-C associated with utilizing models to predict and/or correct substrate particle defect root causes, according to certain embodiments. Methods 400A-C may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiment, methods 400A-C may be performed, in part, by predictive system 110. Method 400A may be performed, in part, by predictive system 110 (e.g., server machine 170 and data set generator 172 of FIG. 1, data set generator 272 of FIG. 2). Predictive system 110 may use method 400A to generate a data set to at least one of train, validate, or test a model (e.g., a physics-based model, a reduced order model, a machine learning model), in accordance with embodiments of the disclosure. Methods 400B-C may be performed by predictive server 112 (e.g., predictive component 114) and/or server machine 180 (e.g., training, validating, and testing operations may be performed by server machine 180). In some embodiments, a non-transitory machine-readable storage medium stores instructions that when executed by a processing device (e.g., of predictive system 110, of server machine 180, of predictive server 112, etc.) cause the processing device to perform one or more of methods 400A-C.

For simplicity of explanation, methods 400A-C are depicted and described as a series of operations. However, operations in accordance with this disclosure can occur in various orders and/or concurrently and with other operations not presented and described herein. Furthermore, not all illustrated operations may be performed to implement methods 400A-C in accordance with the disclosed subject matter. In addition, those skilled in the art will understand and appreciate that methods 400A-C could alternatively be represented as a series of interrelated states via a state diagram or events.

FIG. 4A is a flow diagram of a method 400A for generating a data set for a model, according to some embodiments. Referring to FIG. 4A, in some embodiments, at block 401 the processing logic implementing method 400A initializes a training set T to an empty set.

At block 402, processing logic generates first data input (e.g., first training input, first validating input) that may include one or more of manufacturing parameters, metrology data, process chamber condition data, etc. In some embodiments, the first data input may include a first set of features for types of data and a second data input may include a second set of features for types of data (e.g., as described with respect to FIG. 3). Input data may include historical data and/or data output by a model (e.g., a physics-based model output used for training a machine learning model).

In some embodiments, at block 403, processing logic optionally generates a first target output for one or more of the data inputs (e.g., first data input). In some embodiments, the input includes one or more manufacturing parameters and the target output is an indication related to particle defect formation. In some embodiments, the target output is a recommended corrective action, such as an update to a recipe of a process operation in one chamber to better match processing conditions or processing results of another chamber. In some embodiments, the first target output is predictive data.

At block 404, processing logic optionally generates mapping data that is indicative of an input/output mapping. The input/output mapping (or mapping data) may refer to the data input (e.g., one or more of the data inputs described herein), the target output for the data input, and an association between the data input(s) and the target output. In some embodiments, such as in association with machine learning models where no target output is provided, block 404 may not be executed.

At block 405, processing logic adds the mapping data generated at block 404 to data set T, in some embodiments.

At block 406, processing logic branches based on whether data set T is sufficient for at least one of training, validating, and/or testing a machine learning model, such as synthetic data generator 174 or model 190 of FIG. 1. If so, execution proceeds to block 407, otherwise, execution continues back at block 402. It should be noted that in some embodiments, the sufficiency of data set T may be determined based simply on the number of inputs, mapped in some embodiments to outputs, in the data set, while in some other embodiments, the sufficiency of data set T may be determined based on one or more other criteria (e.g., a measure of diversity of the data examples, accuracy, etc.) in addition to, or instead of, the number of inputs.

At block 407, processing logic provides data set T (e.g., to server machine 180) to train, validate, and/or test machine learning model 190. In some embodiments, data set T is a training set and is provided to training engine 182 of server machine 180 to perform the training. In some embodiments, data set T is a validation set and is provided to validation engine 184 of server machine 180 to perform the validating. In some embodiments, data set T is a testing set and is provided to testing engine 186 of server machine 180 to perform the testing. In the case of a neural network, for example, input values of a given input/output mapping (e.g., numerical values associated with data inputs 210) are input to the neural network, and output values (e.g., numerical values associated with target outputs 220) of the input/output mapping are stored in the output nodes of the neural network. The connection weights in the neural network are then adjusted in accordance with a learning algorithm (e.g., back propagation, etc.), and the procedure is repeated for the other input/output mappings in data set T. After block 407, a model (e.g., model 190) can be at least one of trained using training engine 182 of server machine 180, validated using validating engine 184 of server machine 180, or tested using testing engine 186 of server machine 180. The trained model may be implemented by predictive component 114 (of predictive server 112) to generate predictive data 168 for performing signal processing, or for performing a corrective action associated with manufacturing equipment 124.

FIG. 4B is a flow diagram of a method 400B for utilizing models for adjusting performance of a process chamber, according to some embodiments. At block 410, process logic optionally provides input to a first model. The input may include indications of processing performance of the first chamber, such as recipe set points, component control parameters, measurements (virtual or real) of processing conditions, indications of manufacturing outcomes (e.g., substrate metrology measurements), or the like. The input is associated with a first process chamber, e.g., indicative of performance of processing operations of the first process chamber. The process parameters may correspond to operation of one or more components of the process chamber, including heaters, valves, plasma generation apparatus, chucking devices, pumps, or the like.

At block 412, process logic obtains as output from the first model, first output including one or more target performance metrics of the first process chamber. The first model may be or include a physics-based model or a trained machine learning model, another type of model, or a hybrid model including aspects of multiple types of model. The target performance metrics may be or include process conditions. For example, the input to the first model may include recipe set points or information related to control of components of the first process chamber, and the output of the first model may include predicted in-chamber conditions during the process operations associated with the recipe set points. In some embodiments, the output of the first model may include process results, e.g., predicted metrology of a substrate processed in accordance with the input data.

At block 414, process logic provides, to a second model associated with a second process chamber, the one or more target performance metrics. The target performance metrics (e.g., processing conditions, metrology, etc.) are provided as input to the second model. The second model may be or include one or more machine learning models, physics-based models, or other types of models. The second chamber may be different than the first chamber, e.g., be a different model, be of a different design, have different installed components, or the like.

At block 416, process logic obtains, from the second model, second output. The second output includes process parameters associated with the second process chamber. The process parameters are predicted to correspond with the one or more target performance metrics, with respect to the second process chamber. For example, the second process parameters may be or include recipe set points or control methods for the second chamber, which may be of different design, include different types or numbers of controllable components, etc., than the first chamber. The second process parameters may be predicted to generate the same processing conditions and/or generate the same on-substrate capabilities, properties, or the like as the first process parameters in connection with the first process chamber.

At block 418, process logic performs a corrective action in view of the second output. The corrective action may include one or more actions to improve processing, improve chamber matching, improve chamber performance, or the like. The corrective action may include providing an alert to a user (e.g., indicative of predicted chamber performance or predictive processing parameters), updating a process recipe, updating an equipment constant of the second process chamber, scheduling maintenance, or the like.

At block 420, process logic optionally obtains an indication that the process parameters are associated with measured performance metrics, such as substrate properties or substrate processing parameters. The measured performance metrics may be different than the target performance metrics. For example, one or more models may be generating incorrect predictions of the performance of a process chamber. Process logic may perform retraining of one or more related models, e.g., updating parameters of trained machine learning models based on differences between measured and predicted properties.

At block 422, process logic optionally obtains an indication that the process parameters correspond to measured performance metrics that are different from target performance metrics, e.g., as described with respect to block 420. Responsive to the differences, data indicative of the differences between the measured and target performance metrics may be provided to a further model or sets of models. The further model or set of models produces as output an update to process parameters, e.g., to correct differences between predicted and measured performance of a process chamber.

FIG. 4C is a flow diagram of a method 400C for training a machine learning model for performing chamber matching operations, according to some embodiments. One or more machine learning models may be used for transferring recipes between different chambers, e.g., different models, updated designs, or the like. In some embodiments, a model may be configured for transferring recipes from one target chamber to another. For example, a fabrication facility may include many chambers of a first type, model, or design, and perform many different process operations using these chambers. The facility may begin replacing this chamber type with a different chamber type, e.g., an updated model, which may include different components, be configured differently, include different controls, etc. It may be of value to generate a model that automates transfer of recipes between the old chamber type and the new chamber type, e.g., without an intermediate operation related to matching chamber results.

At block 430, training data is curated. Curating the training data may include performing comparison of process result data, e.g., real or simulated sensor data indicative of process conditions, on-substrate outcomes, or the like. Curating the training data may include determining process inputs to the two different chambers that correspond to equivalent (e.g., within a threshold) process outcomes. Curating the training data may include separating training data into subsystems, e.g., subsystems that contribute to particular process conditions may be correlated, even when other process conditions are not the same. Curating the training stet data includes determining that first process inputs of a first process chamber correspond to second process inputs of a second process chamber.

At block 432, process logic obtains training input data comprising first process input to the first process chamber. The first process inputs correspond to a set of process performance results. The set of process performance results may include measured or estimated (e.g., virtual sensor data) values of properties in the chamber, processing conditions, etc. The set of process performance results may be or include substrate outcomes, e.g., defect probabilities, substrate metrologies, etc.

At block 434, process logic obtains target output. The target output comprises second process inputs in association with a second process chamber. The second process chamber is different than the first process chamber. The second process chamber may be of a different design or model than the first chamber. The second process inputs further correspond to the process performance results, e.g., the same process performance results (within a threshold) as the training input data.

At block 436, process logic trains a machine learning model by providing the training input data and the target output data to generate a trained machine learning model configured to obtain as input a set of process inputs to the first process chamber and generate as output a set of process inputs to the second process chamber. The sets of process inputs may correspond to each other, e.g., the first set provided to the first chamber may be predicted to generate similar process outcomes to processing with the second set provided to the second chamber.

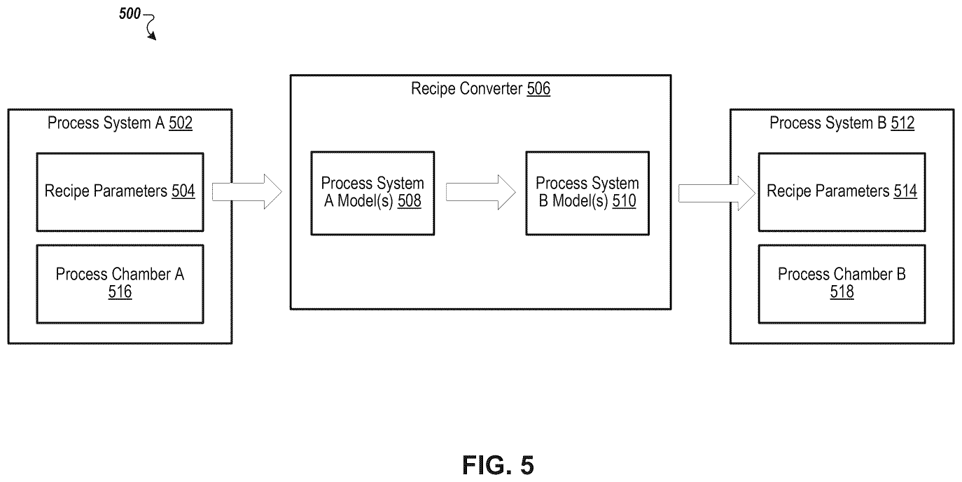

FIG. 5 is a block diagram depicting a flow 500 for converting a process recipe for use in a second process system, according to some embodiments. A process system A 502 may include a number of components for performing substrate processing operations. For example, process system A 502 may include a process chamber, including all associated components, one or more computing systems, data storage, metrology systems, sensors and sensor systems, network connection, etc. Process system A 502 may include one or more controllers for generating and/or providing control signals to components of process chamber A 516. Process system A 502 may include stored data (e.g., stored in one or more data stores, stored as non-transitive machine-readable media, etc.) associated with operation of process system A 502, e.g., including sensor data, manufacturing parameter data, metrology data, etc.

Process system A 502 includes recipe parameters 504. Recipe parameters 504 may include recipe set points, recipe control signals, process knobs, manufacturing parameters, or other parameters that are utilized in combination with process chamber A to perform substrate processing operations, to manufacture substrates, etc. Recipe parameters 504 may have been generated in accordance with best known practices, may have been iterated, improved, and changed over a period including many processing runs. Recipe parameters 504 may include reliable parameters for generating substrates of a particular design, reliable parameters for a class of substrates, parameters for performing a target operation on a substrate (such as deposition of a film of a target thickness or uniformity), or the like.

Recipe parameters 504 are provided to recipe converter 506. Recipe converter 506 may include a number of models associated with process system A 502 and process system B 512. Recipe converter 506 may include resources (e.g., processors, instructions, computer-readable media, etc.) to perform additional operations, such as providing data to and receiving data from models associated with process system A 502 and process system B 212, resources for operating one or more models as an inverse model (e.g., instructions for execution of an optimization-type problem for inversion operations of process system B models 510), etc.

Recipe parameters 504 are provided to process system A model 508. In some embodiments, recipe parameters 504 may include control parameters of a target system. In some embodiments, recipe parameters 504 may include control parameters of a number of systems. Recipe parameters 504 may include set points of one or more target systems of process system A 502. Recipe parameters 504 may include parameters associated with one or more heating elements, heating zones, lamps, or the like. Recipe parameters 504 may include power provided to heating zones, target temperature readings at one or more temperature sensors or locations of process system A 502, or the like. Recipe parameters 504 may include parameters associated with gas flow, including one or more flow zones. Recipe parameters 504 may include actuator positions, valve opening positions, target flow rates of one or more process gases, or the like. Recipe parameters 504 may include target pressure, substrate position, substrate movement (e.g., rotation), plasma power, plasma bias voltage, or any other parameters related to substrate processing operations in connection with process system A 502.

Process system A model 508 receives the recipe parameters 504, and generates output based on the recipe parameters 504. Process system A model 508 may include one or more models configured to represent performance of process system A 502. Process system A model 508 may include one or more machine-learning models, statistical models, physics-based models, rule-based models, heuristic models, or the like. Process system A model 508 generates as output indications of performance of process system A 502 in connection with the provided recipe parameters 504. The output may include substrate performance metrics, such as thickness, thickness profile, uniformity, resistivity, crystal quality, film quality, film thickness, or any other parameter of interest of the substrate. The output may include indications of process conditions, such as temperature and gas flow conditions proximate a substrate disposed for processing in process system A 502.

Output of process system A model 508 if utilized for process system B model 510. In some embodiments, an optimization may be performed, and inputs to process system B model 510 may be varied until output of process system B model 510 matches (within a target threshold error) output of process system A model 508. In some embodiments, outputs of process system A model 508 may be provided as input to process system B model 510. Results obtained from process system B model 510 may include one or more recipe parameters. The recipe parameters may correspond to the performance data generated by process system A model 508. The recipe parameters may be parameters related to control of components of process system B 512, which may be different than components of process system A 502. Output of recipe convertor 506 may be provided to process system B 512 as recipe parameters 514. Recipe parameters 514 may be recipe parameters predicted to enable control of process chamber B 518 to generate output corresponding to the output generated by process system A 502 when parameters of recipe parameters 504 are executed by process chamber A 516. For example, recipe converter 506 may be used to convert a recipe operating in connection with process chamber A 516 to a recipe in connection with process chamber B 518, while achieving the same results using process chamber B 518 as process chamber A 516.

Recipe converter 506 may be utilized for generating process recipes for a new, repurposed, updated, or different chamber than the chamber for which process recipe parameters, best known methods, or the like are in place. Recipe converter 506 may be utilized in transferring a recipe from one type of process chamber (e.g., one model of process chamber) to another (e.g., a chamber of different design than the original chamber). Recipe converter 506 may be utilized in transferring a recipe from one chamber to an updated chamber, e.g., a similar chamber but one with somewhat different components, features, controls, or the like. Recipe converter 506 may be utilized in transferring a recipe from one chamber to another nominally identical chamber, e.g., with differences (captured in process system A model 508 and process system B model 510) that are within manufacturing tolerances, due to different ages or histories of the chamber, or the like. Recipe converter 506 may assist in reducing an on-boarding time of process chamber B 518 while being adapted to a new process, new substrate design, or the like. Recipe convertor 506 may enable efficient and cost-effective generation of process recipes for agile adjustment of chamber performance in a manufacturing facility.

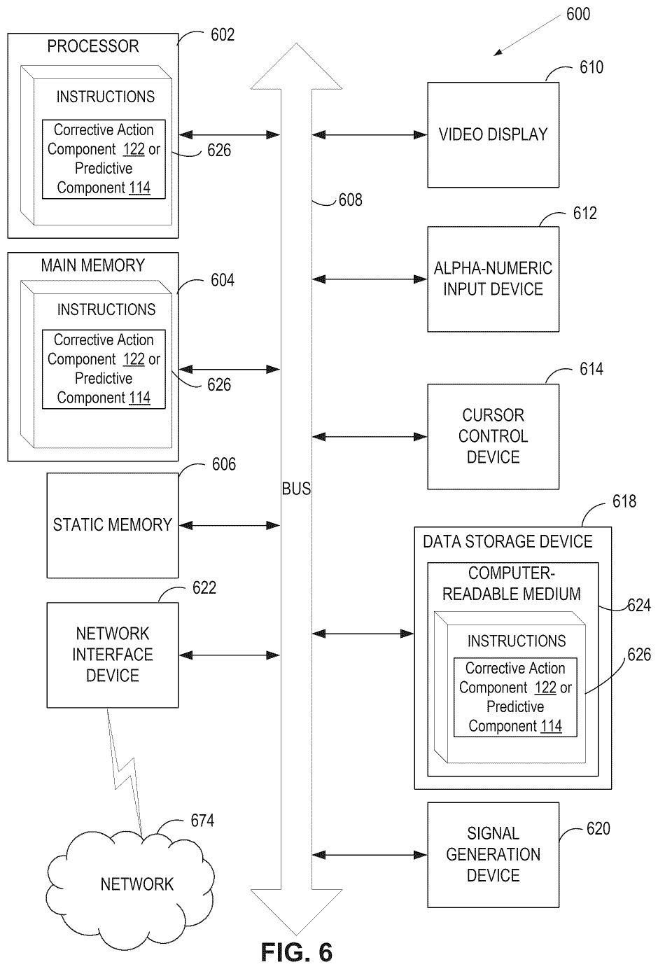

FIG. 6 is a block diagram illustrating a computer system 600, according to some embodiments. In some embodiments, computer system 600 may be connected (e.g., via a network, such as a Local Area Network (LAN), an intranet, an extranet, or the Internet) to other computer systems. Computer system 600 may operate in the capacity of a server or a client computer in a client-server environment, or as a peer computer in a peer-to-peer or distributed network environment. Computer system 600 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 600 may include a processing device 602, a volatile memory 604 (e.g., Random Access Memory (RAM)), a non-volatile memory 606 (e.g., Read-Only Memory (ROM) or Electrically-Erasable Programmable ROM (EEPROM)), and a data storage device 618, which may communicate with each other via a bus 608.

Processing device 602 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 600 may further include a network interface device 622 (e.g., coupled to network 674). Computer system 600 also may include a video display unit 610 (e.g., an LCD), an alphanumeric input device 612 (e.g., a keyboard), a cursor control device 614 (e.g., a mouse), and a signal generation device 620.

In some embodiments, data storage device 618 may include a non-transitory computer-readable storage medium 624 (e.g., non-transitory machine-readable medium, non-transitory machine-readable storage medium, or the like) on which may store instructions 626 encoding any one or more of the methods or functions described herein, including instructions encoding components of FIG. 1 (e.g., predictive component 114, corrective action component 122, model 190, etc.) and for implementing methods described herein. The non-transitory machine-readable storage medium may store instructions which are used to execute methods related to transferring or updating process input parameters, chamber matching, or the like.

Instructions 626 may also reside, completely or partially, within volatile memory 604 and/or within processing device 602 during execution thereof by computer system 600, hence, volatile memory 604 and processing device 602 may also constitute machine-readable storage media.

While computer-readable storage medium 624 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” “reducing,” “generating,” “correcting,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and embodiments, it will be recognized that the present disclosure is not limited to the examples and embodiments described. The scope of the disclosure should be determined with reference to the following claims, along with the full scope of equivalents to which the claims are entitled.

What is claimed is:

1. A method comprising:
obtaining, from a first model associated with a first process chamber, first output comprising one or more target performance metrics of the first process chamber;
providing, to a second model associated with a second process chamber, the one or more target performance metrics as first input;
obtaining, from the second model, second output comprising first process parameters in association with the second process chamber, wherein the first process parameters are predicted to correspond with the one or more target performance metrics; and
performing a corrective action in view of the second output.

2. The method of claim 1, wherein the first model comprises a physics-based model, a trained machine-learning model, or a hybrid data-based and physics-based model.

3. The method of claim 1, further comprising providing second input to the first model, wherein the second input comprises second process parameters in association with the first process chamber, and wherein the one or more target performance metrics correspond to the second process parameters.

4. The method of claim 1, wherein the one or more target performance metrics comprise process conditions proximate a substrate support of the first process chamber, or predicted properties of a substrate processed by the first process chamber.

5. The method of claim 1, wherein the second process chamber comprises one or more components that are different than the first process chamber.

6. The method of claim 1, wherein the first process parameters include parameters determining operation of one or more of:
one or more heaters of the second process chamber;
one or more valves of the second process chamber; or
one or more plasma generation apparatuses of the second process chamber.

7. The method of claim 1, further comprising:
obtaining an indication that the first process parameters are associated with measured performance metrics, which comprise different values than the target performance metrics;
providing a difference between the target performance metrics and the measured performance metrics to a third model; and
obtaining an update to the first process parameters from the third model, based on the difference between the target performance metrics and the measured performance metrics.

8. The method of claim 1, further comprising:
obtaining an indication that the first process parameters are associated with measured performance metrics, which comprise different values than the target performance metrics;
updating one or more parameters of the second model based on the target performance metrics and the measured performance metrics.

9. The method of claim 1, wherein the corrective action comprises one or more of:
providing an alert to a user;
updating a process recipe;
updating an equipment constant of the second process chamber; or
scheduling maintenance of the first process chamber or the second process chamber.

10. A non-transitory machine-readable storage medium storing instructions which, when executed, cause a processing device to perform operations comprising:
obtaining, from a first model associated with a first process chamber, first output comprising one or more target performance metrics of the first process chamber;
providing, to a second model associated with a second process chamber, the one or more target performance metrics as first input;
obtaining, from the second model, second output comprising first process parameters in association with the second process chamber, wherein the first process parameters are predicted to correspond with the one or more target performance metrics; and
performing a corrective action in view of the second output.

11. The non-transitory machine-readable storage medium of claim 10, wherein the first model comprises a physics-based model, a trained machine-learning model, or a hybrid data-based and physics-based model.

12. The non-transitory machine-readable storage medium of claim 10, wherein the operations further comprise providing second input to the first model, wherein the second input comprises second process parameters in association with the first process chamber, and wherein the one or more target performance metrics correspond to the second process parameters.

13. The non-transitory machine-readable storage medium of claim 10, wherein the one or more target performance metrics comprise process conditions proximate a substrate support of the first process chamber, or predicted properties of a substrate processed by the first process chamber.

14. The non-transitory machine-readable storage medium of claim 10, wherein the second process chamber comprises one or more components that are different than corresponding components of the first process chamber.

15. The non-transitory machine-readable storage medium of claim 10, wherein the operations further comprise:
obtaining an indication that the first process parameters are associated with measured performance metrics, which comprise different values than the target performance metrics;
providing a difference between the target performance metrics and the measured performance metrics to a third model; and
obtaining an update to the first process parameters from the third model, based on the difference between the target performance metrics and the measured performance metrics.

16. The non-transitory machine-readable storage medium of claim 10, wherein the operations further comprise:
obtaining an indication that the first process parameters are associated with measured performance metrics, which comprise different values than the target performance metrics;
updating one or more parameters of the second model based on the target performance metrics and the measured performance metrics.

17. The non-transitory machine-readable storage medium of claim 10, wherein the corrective action comprises one or more of:
providing an alert to a user;
updating a process recipe;
updating an equipment constant of the second process chamber; or
scheduling maintenance of the first process chamber or the second process chamber.

18. A system comprising memory and a processing device coupled to the memory, wherein the processing device is to:
obtain, from a first model associated with a first process chamber, first output comprising one or more target performance metrics of the first process chamber;
provide, to a second model associated with a second process chamber, the one or more target performance metrics as first input;
obtain, from the second model, second output comprising first process parameters in association with the second process chamber, wherein the first process parameters are predicted to correspond with the one or more target performance metrics; and
perform a corrective action in view of the second output.

19. The system of claim 18, wherein the one or more target performance metrics comprise process conditions proximate a substrate support of the first process chamber, or predicted properties of a substrate processed by the first process chamber.

20. The system of claim 18, wherein the corrective action comprises one or more of:
providing an alert to a user;
updating a process recipe;
updating an equipment constant of the second process chamber; or
scheduling maintenance of the first process chamber or the second process chamber.
